(19) United States
(12) Patent Application Publication
(10) Pub. No.: US 2017/0358658 A1
(43) Pub. Date: Dec. 14, 2017

(54) METAL OXIDE METAL FIELD EFFECT TRANSISTORS (MOMFETS)

(71) Applicant: INTEL CORPORATION, Santa Clara, CA (US)

(72) Inventors: Rafael RIOS, Portland, OR (US); Kelin J. KUHN, Aloha, OR (US); Seiyon KIM, Portland, OR (US); Justin R. Weber, Hillsboro, OR (US)

(21) Appl. No.: 15/506,205

(22) PCT Filed: Sep. 26, 2014
(86) PCT No.: PCT/US2014/057867

§ 371 Date: Feb. 23, 2017

(51) Int. Cl. H01L 29/66; H01L 29/06; H01L 29/423

(52) U.S. Cl. CPC H01L 29/66439; H01L 29/4238; H01L 29/42356; H01L 29/42364; H01L 29/0669

(57) ABSTRACT

Embodiments of the invention include metal oxide metal field effect transistors (MOMFETs) and methods of making such devices. In embodiments, the MOMFET device includes a source and a drain with a channel disposed between the source and the drain. According to an embodiment, the channel has at least one confined dimension that produces a quantum confinement effect in the channel. In an embodiment, the MOMFET device also includes a gate electrode that is separated from the channel by a gate dielectric. According to embodiments, the band-gap energy of the channel may be modulated by changing the size of the channel, the material used for the channel, and/or the surface termination applied to the channel. Embodiments also include forming an type device and a P-type device by controlling the work-function of the source and drain relative to the conduction band and valance band energies of the channel.

### FIELD OF THE INVENTION

Embodiments generally relate to transistor devices. More specifically, embodiments relate to metal oxide metal field effect transistors (MOMFETs) and methods of making such devices.

### BACKGROUND OF THE INVENTION

Continuous device scaling leads to increasingly smaller and confined channels. As the size of transistors continue to decrease, limitations in the material properties are becoming hurdles that are increasingly harder to overcome. For example, as the dimensions of the channel decrease, the band-gap of semiconductor materials begins to increase due to the effects of quantum confinement. Bulk silicon, for example, typically has a band-gap between approximately 1.0 eV and 1.1 eV. However, when the channel thickness decreases below approximately 10 nm the band-gap may increase to 1.5 eV or larger. Confined channels also reduce the total charge that can be induced in a semiconductor channel because of the reduction in the density of states. As such, the efficiency of the transistor is reduced.

Additionally, as device scaling continues, manufacturing limitations may also limit further reductions in size. As the channel length is decreased to less than 10 nm, the proper doping concentrations may be obtained after several atoms of the dopant have been implanted. For example, only one or two atoms of the dopant may be needed to provide the proper doping concentration. After implantation, the dopants are also susceptible to diffusion. At such small scales, and with so few dopant atoms, unwanted diffusion of the dopant species becomes increasingly harder to control. As such, device scaling increases the difficulty of manufacturing transistor devices.

Furthermore, demands for increased transistor density are driving manufactures to utilize 3-dimensional (3-D) integration. Since the source, drain, and channel regions typically require highly ordered semiconductor crystals, 3-D integration requires wafer bonding. Wafer bonding greatly increases the cost of production and requires additional processing operations that reduce throughput.

### BRIEF DESCRIPTION OF THE DRAWINGS

FIG. 1A is a graph that illustrates the band-gap energy as a function of wire radius for Sn nanowires with various surface termination species.

FIGS. 1B-1E are graphs that illustrate the conduction band and the valance band relative to vacuum for Sn nanowires with various surface termination species.

FIG. 2A is an illustration of a planar MOMFET device, according to an embodiment.

FIG. 2B is an illustration of a planar MOMFET device that includes 3-D integration, according to an embodiment.

FIGS. 3A-3F are cross-sectional illustrations of a process for forming a planar MOMFET device, according to an embodiment.

FIGS. 4A-4E are cross-sectional illustrations of a process for forming a CMOM inverter, according to an embodiment.

FIGS. 5A-5D are cross-sectional illustrations of a process for forming a CMOM inverter, according to an additional embodiment.

FIGS. 6A-6C are cross-sectional illustrations of a process for forming a nanowire MOMFET device, according to an embodiment.

FIG. 7 is a cross-sectional illustration of a nanowire MOMFET device, according to an embodiment.

FIG. 8 is an illustration of a schematic block diagram of a computer system that utilizes a MOMFET device, according to an embodiment.

### DETAILED DESCRIPTION OF THE INVENTION

Embodiments of the invention include metal oxide metal field effect transistors (MOMFETs) and methods of forming such devices.

Embodiments of the invention are able to overcome the previous manufacturing and material property limitations of semiconductor based transistor devices that are present when the devices are scaled to the point that the channel becomes confined in at least one dimension. As used herein, a “confined” channel is a channel that has a dimension that is small enough to produce a quantum confinement effect in the channel material. A quantum confinement effect in a material results in the energy spectrum turning from a continuous energy spectrum into a discrete energy spectrum. As such, carriers (i.e., holes and electrons) are only able to occupy discrete energy levels. For example, a metal or a semimetal may have a continuous energy spectrum in bulk form, but as a dimension of the material becomes confined, the carriers are only able to occupy discrete energy levels. Accordingly, a band-gap is formed in the material that may then be used to fabricate transistor devices such as a MOMFET according to embodiments of the invention described herein.

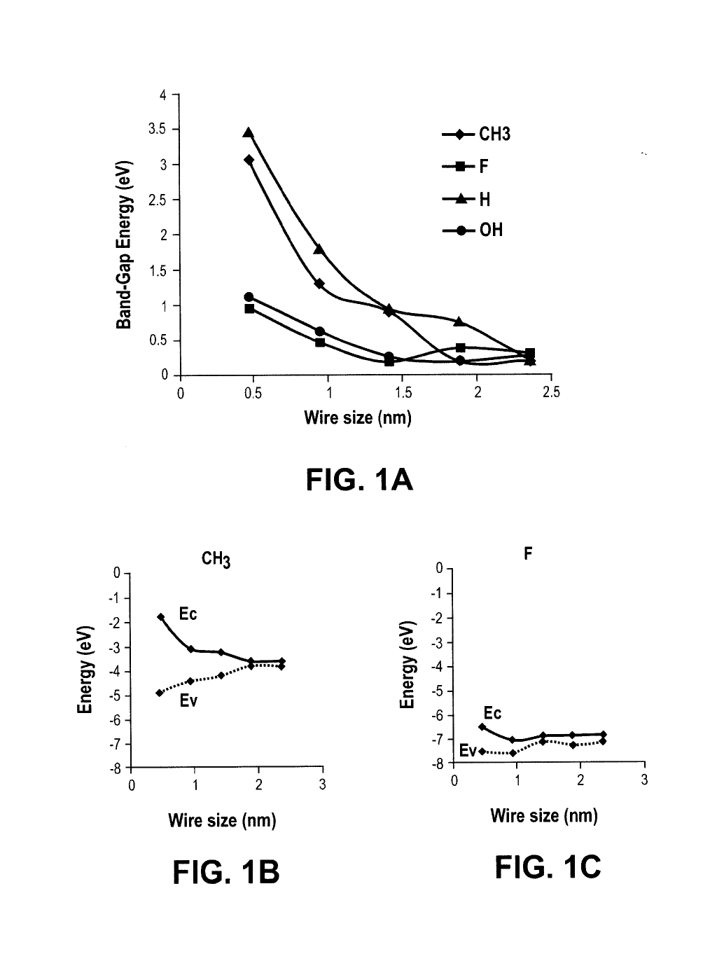

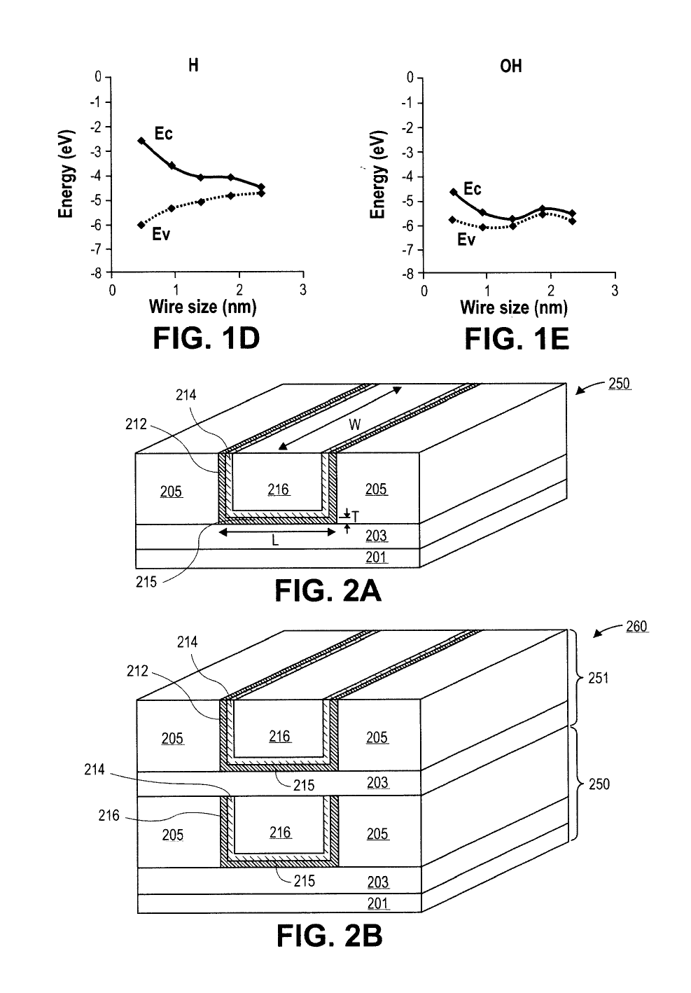

Embodiments of the invention provide one or more variables that can be controlled to obtain a desired band-gap in the channel. By way of example, the band-gap energy may by modulated by choosing different materials for the channel, changing the size of the confined dimension of the channel, changing the surface termination of the channel, or any combination thereof. FIG. 1A illustrates the effect that the size of the channel and the surface termination of the channel have on the band-gap energy. In FIG. 1A, the band-gap energy as a function of wire radius for <100> Sn nanowires with different surface termination species is plotted. As shown in the exemplary embodiment depicted in FIG. 1A, confined Sn nanowires obtain a band-gap that may be utilized to form a transistor device. Furthermore, for any given diameter of the nanowire, the band-gap energy may be modulated by using different surface termination species. By way of example, surface termination species may include CH₃, F, H, and OH. The use of different surface termination species may also be used to modulate the electron affinity (i.e., the conduction band energy relative to the vacuum level) of the channel material. FIGS. 1B-1E provide a plot of the conduction band (E_{C}) and the valance band (E_{V}) relative to vacuum for <100> Sn wires as a function of wire radius for each surface termination shown in FIG. 1A.

It is noted that the data plotted in FIGS. 1A-E are qualitatively correct, since spin orbit splitting is not included in the data. As such, it is to be appreciated that the values of the band-gap energy and electron affinity at various radii and for different termination species are not limiting and are provided for illustrative purposes. Additionally, while Sn nanowires are provided as an exemplary illustration, similar quantum confinement effects may be produced in channels that are not nanowires and in materials other than Sn. For example, channels confined in a single dimension (e.g., a thin sheet) and in channels made from other metallic or semimetallic materials may also be used according to embodiments of the invention.

According to embodiments, the confined channels are inherently bipolar and are able to conduct holes and electrons. However, instead of relying on dopants to produce N-type or P-type transistors, the materials used for the source/drain (S/D) regions and the gate electrode can control the conductivity type according to embodiments of the invention. According to embodiments, the work-function of the S/D region relative to the conduction band and the valance band of the channel determines whether the device will be an N-type or P-type device, as is described in greater detail below. As such, issues involving diffusion of dopants that occur when using semiconductor materials are avoided.

Referring now to FIG. 2A, a planar MOMFET device 250 according to an embodiment is illustrated. In an embodiment, the planar MOMFET device 250 may be formed over a substrate 201. Embodiments include a substrate 201 that is rigid enough to provide support to the device during fabrication operations. The substrate 201 may be a non-crystalline or crystalline material. By way of example, the substrate 201 may be glass, sapphire, silicon, polymeric, or any other substrate on which an insulating layer can be deposited. Embodiments of the invention are not limited to typical semiconducting substrates with highly ordered crystalline structures, such as silicon wafers, because the semiconducting properties of the MOMFET device 250 are not dependent on the semiconducting behavior of those materials.

As illustrated, an insulating layer 203 is formed over a top surface of the substrate 201. According to an embodiment, the insulating layer 203 may be any insulating material typically used in semiconductor processing. For example, the insulating layer 203 may be an oxide, such as a silicon oxide, or a nitride. According to an embodiment of the invention, the thickness of the insulating layer may have a thickness chosen to provide the desired insulative protection between layers formed above and below the insulating layer 203. By way of example, embodiments include an insulating layer 203 that has a thickness of approximately 50 nm.

The MOMFET device 250 includes S/D regions 205. In an embodiment, the S/D regions may be formed from a metallic or semi-metallic material. In an embodiment, the material chosen for the S/D regions may be a material that is highly conductive. For example, the performance of the MOMFET device 250 may be improved when a high conductivity material, such as tungsten, is used for the S/D regions 205. Additional embodiments include a S/D region 205 that is the same material as the channel 215.

A confined channel 215 is formed between the S/D regions 205. In an embodiment, the channel 215 is formed from a material that is conductive when in bulk form, but obtains a band-gap when the channel is confined in a dimension that is sufficiently small enough to produce a quantum confinement effect in the channel. According to embodiments, the channel 215 has one or more confined dimensions. For example, in FIG. 2A, the channel 215 is confined in at least its thickness dimension T. The thickness T of the channel 215 needed to produce a quantum confinement effect is dependent on the material chosen for the channel 215, and on the surface termination (if any) that is applied to the channel.

Embodiments include a channel thickness T that may be less than approximately 5 nm. Additional embodiments include a channel thickness T that is less than approximately 3 nm. In an embodiment, the channel may have a thickness T that is between approximately 0.5 nm and approximately 5 nm. In an embodiment, the thickness of the channel 215 is chosen to provide a desired band-gap energy. By way of example, the thickness of the channel material may produce a band-gap energy in the channel that is less than 1.5 eV. An additional embodiment may include a channel thickness that produces a band-gap energy in the channel that is between approximately 0.5 eV and approximately 1.5 eV.

According to an embodiment, the channel 215 may be a semimetal, such as Sn, Pb, As, Sb, or Bi. It is to be appreciated that the group of materials that are considered to be “semimetals” does not include Si or Ge, because “semimetals” are defined as not having a band-gap when in bulk form and Si and Ge both have band-gaps when in bulk form. Additional embodiments include a channel 215 that is a bismide, such as, InBi or GaBi. In an embodiment, the channel 215 may also be a rare-earth pnictides, such as LaAs, ScP, YSb, or ErAs. In an embodiment, the channel 215 may also include a Group IV-b/IV-a compound, such as TiC or HfSi. In an embodiment, the channel 215 may include a transition metal compound, such as FeSi. Another embodiment may include a channel 215 that is a silicide, such as NiSi, TiSi, or CoSi. According to an embodiment, the channel 215 may be the same material used for the S/D regions 205.

In addition to controlling the thickness of the channel 215 to provide the desired band-gap, embodiments of the invention may also include forming a surface termination species over the channel 215 in order to modulate the band-gap of the channel. For example, referring back to FIG. 1A, a 1.0 nm diameter Sn nanowire with a hydrogen surface termination produces a band-gap that is larger than the band-gap of a 1.0 nm diameter Sn nanowire with a fluorine surface termination.

Embodiments may also use the surface termination species that is applied to the channel 215 to determine whether the device is an N-type or P-type device. When the Fermi level of the channel 215 is closer to the conduction band (E_{C}) an N-type device is produced, whereas a Fermi level that is closer to the valance band (E_{V}) produces a P-type device. The surface termination species can be used to modulate the position of the conduction band and the valence band of the channel 215 by altering the electron affinity of the channel 215. A channel 215 with a low electron affinity produces a conduction band (E_{C}) that is higher relative to a channel 215 with a high electron affinity. For example, referring back to FIGS. 1B and 1E, the electron affinity of a Sn nanowire with a CH₃ surface termination is lower than the electron affinity of a Sn nanowire with an OH surface termination for a given wire diameter.

Referring back to FIG. 2A, the channel 215 may have a channel length L. By way of example, the channel length may be approximately 10 nm or less. According to an embodiment, the channel length L is less than 5 nm. The channel may also have a channel width W that extends substantially along the width of the gate electrode 216. Since the channel 215 is confined in the thickness dimension T, the channel length L and the channel width W do not need to be confined dimensions according to embodiments of the invention. However, embodiments may also include a channel 215 that is confined in the channel width W, channel length L, channel thickness T, or any combination thereof.

In an embodiment, a sidewall layer 212 may be formed along the sidewalls of the S/D region. By way of example, the sidewall layer 212 is the same material as the channel 215. In some embodiments, the sidewall layer 212 is a remnant of the processing method used to form the MOMFET 250, and may be considered a portion of the S/D region 205. According to additional embodiments, the layer 212 may be omitted.

As illustrated in FIG. 2A, a gate electrode 216 is separated from the S/D regions 205 and the channel 215 by a gate dielectric 214. In an embodiment, the gate dielectric may be a high-k dielectric. By way of example, the gate dielectric may be hafnium oxide, zirconium oxide, or the like. In an embodiment, the gate electrode 216 is a conductive material and may be a chosen to have a work-function that will provide the desired threshold voltage for the device.

According to embodiments, the work-function of the S/D regions 205 may be used to determine the conductivity type of the MOMFET device 250. Specifically, the work-function of the S/D regions 205 relative to the conduction band energy (E_{C}) and valence band energy (E_{V}) of the channel 215 determines whether the MOMFFET device is P-type or N-type device. For example, if the work-function of the S/D regions 205 is close to or less than the conduction band energy of the channel 215, an N-type device forms with preferential conduction of electrons. Alternatively, if the work-function of the S/D regions 205 is close to or greater than the valence band energy of the channel, a P-type device forms with preferential conduction of holes. In embodiments where the work-function of the S/D regions 205 is near the middle of the band-gap of the channel 215, then both carriers can conduct depending on the applied gate bias. However, such embodiments may suffer from low current (I) on/off ratios and low drive currents due to the high energy barrier between the S/D regions 205 and the channel 215. Accordingly, instead of having to relying on dopants like traditional semiconducting transistors, the conductivity type of a MOMFET device 250 may be tailored by changing the materials used in the S/D regions 205, changing the materials used in the channel 215, and/or changing the surface terminations applied to the channel.

According to an additional embodiment, when the S/D regions 205 are formed with the same material as the channel 215, the conductivity type of the MOMFET device 250 may also be determined by controlling the work-function of the gate electrode 216 relative to the channel 215. In such an embodiment, the MOMFET device is ambipolar and is able to conduct both carrier types. In an embodiment, the work-function of the gate electrode 216 may be used to set the turn on voltage such that one conductivity type becomes dominant. For example, a gate electrode work-function that is close to the conduction band (E_{C}) of the channel may be used to form an N-type device, whereas a gate electrode work-function close to the valence band (E_{V}) of the channel may be used to form a P-type device.

The use of semimetalic and metallic materials for the S/D regions and the channel also reduces the difficulty of 3-D integration. Without the need to form MOMFETs on a highly crystalline semiconductor substrate, multiple layers of MOMFETs may be stacked on top of each other without the need for expensive and time consuming wafer bonding processes.

Such a 3-D integrated device is illustrated in FIG. 2B. According to embodiments, the 3-D integrated MOMFET 260 may include a plurality of MOMFET devices stacked on top of each other. For example, the embodiment illustrated in FIG. 2B shows a second MOMFET device 251 stacked above a first MOMFET device 250. According to embodiments, 3-D integration is possible without the need for wafer bonding processes. Since the S/D regions 205 and the channel 215 do not need to be formed on a traditional semiconducting substrate, such as a silicon wafer, there is no need for a crystalline substrate to be formed above the first MOMFET device 250. Instead, embodiments may include forming an additional insulation layer 203 over the first MOMFET device 250 in order to electrically isolate the devices from each other. The second MOMFET device 251 may then be formed on the second insulation layer 203. Accordingly, increased transistor density may be obtained without increasing the complexity of device fabrication.

In an embodiment, the second MOMFET 251 may be substantially similar to the first MOMFET device 250. Alternative embodiments may include a second MOMFET device 251 that is different than the first MOMFET device 250. By way of example, the second MOMFET device 251 may be a P-type device, whereas the first MOMFET device 250 may be an N-type device. Additional embodiments include a second MOMFET device 251 that is oriented in a different direction than the first MOMFET device 251. Further embodiments may also include one or more intervening layers, such as interconnect layers that are formed between first and second MOMFET devices 250, 251.

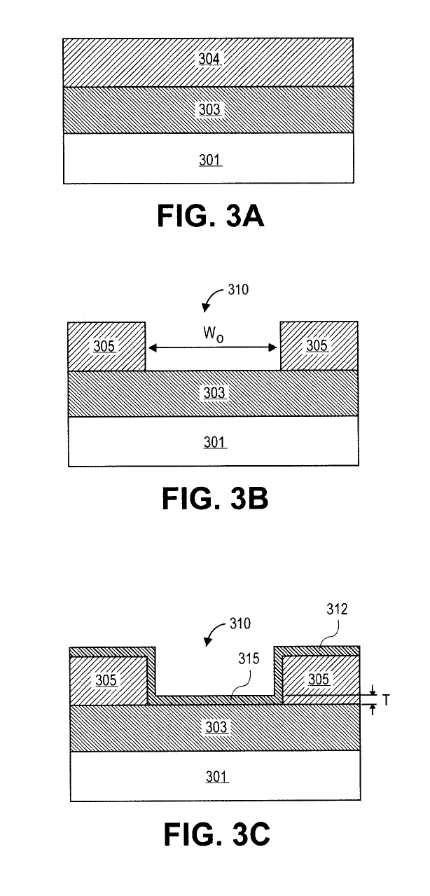

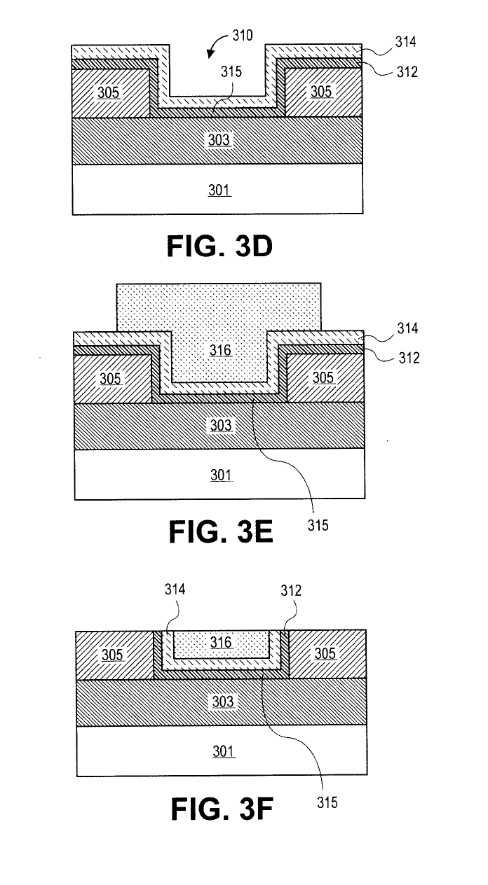

FIGS. 3A-3F are cross-sectional illustrations of various processing operations that may be used to form MOMFET devices according to embodiments of the invention. Beginning at FIG. 3A, a substrate 301 is provided. In an embodiment, the substrate 301 may be a non-crystalline or crystalline material. However, embodiments may utilize a crystalline structure for the substrate according to certain embodiments. For example, a semiconductor material, such as a silicon wafer, may be used as the substrate 301. The use of a crystalline substrate may provide a more uniform thickness and a highly planar surface. Accordingly, such embodiments may improve the ease of fabrication due to the planar surface.

According to an embodiment, an insulating layer 303 may be formed over the substrate 301. In an embodiment the insulating layer 303 may be any insulating layer commonly used in semiconductor fabrication. For example, the insulating layer may be an aluminum oxide, a silicon oxide, or a nitride. In an embodiment, the insulating layer 303 may be formed with chemical vapor deposition (CVD), physical vapor deposition (PVD), or atomic layer deposition (ALD).

In an embodiment, a source/drain (S/D) layer 304 may be deposited over the insulating layer 303. In an embodiment, the S/D layer 304 may be a low contact resistance material, such as a metallic material. For example, the S/D layer 304 may be tungsten. In an embodiment, the S/D layer 304 may be formed with a material that has a specific work-function. Using the work-function as a criteria for selecting the material for the S/D layer 304 allows for the conductivity type of the MOMFET to be determined. Additional embodiments include a S/D layer 304 that is the same material that will be used for the channel 315.

Referring now to FIG. 3B, the S/D layer 304 is patterned to define the S/D regions 305. As illustrated, an opening 310 is formed through the S/D layer 304 to expose a portion of the insulating layer 303. Embodiments of the invention may utilize typical patterning and etching processes known in the art in order to form the opening 310. In an embodiment, the openings may be formed with a multiple patterning process. A multiple patterning process may be desirable when the opening 310 is sufficiently small, such that the resolution of lithography techniques are insufficient to pattern the S/D regions 305. By way of example, the opening may have a width W_{O} that is less than approximately 10 nm. According to an embodiment, the width W_{O} may be approximately 5 nm or less.

Referring now to FIG. 3C, the channel 315 may be deposited over the exposed surface of the insulating layer 303 between the S/D regions 305 according to an embodiment. During the deposition of the channel 315, channel material 312 may also deposit along the sidewalls and top surfaces of the S/D regions 305. While channel material 312 may formed over the entire exposed surface, it is noted that the channel 315 of the MOMFET device is located along the bottom surface of the opening 310 between the S/D regions, according to the embodiment depicted in FIG. 3C. As such, the portions of the channel material 312 formed along the sidewalls of the S/D regions 305 may not be considered part of the channel 315, according to an embodiment.

In an embodiment, the channel 315 is formed with a material that develops a band-gap when the thickness T of the channel 315 is small enough to produces a quantum confinement effect in the channel 315. In an embodiment, the thickness T of the channel 315 is chosen to provide the desired band-gap. For example, as the thickness of the channel 315 is decreased, the band-gap increases. For example, when the channel material is Sn, a thickness T between approximately 1 nm and approximately 5 nm may produce the desired band-gap in the channel 315. By way of example, the desired band-gap in the channel 315 may be between approximately 0.5 eV and 1.5 eV. Embodiments of the invention allow for precise control of the thickness T through use of various deposition techniques. For example, ALD may be able to produce channel thicknesses T that are less than approximately 3.0 nm. Additional embodiments include deposition of the channel 315 with CVD or PVD.

Embodiments include a channel 315 that is a semimetal, such as, Sn, Pb, As, Sb, or Bi. It is to be appreciated that the group of materials that are considered to be “semimetals” does not include Si or Ge, because “semimetals” are defined as not having a band-gap when in bulk form and Si and Ge both have band-gaps when in bulk form. Additional embodiments include a channel 315 that is a bismide, such as, InBi or GaBi. In an embodiment, the channel 315 may also be a rare-earth pnictides, such as LaAs, ScP, YSb, or ErAs. In an embodiment, the channel 315 may also be a Group IV-b/IV-a compound, such as TiC or HfSi. In an embodiment, the channel 315 may be a transition metal compound, such as FeSi. Another embodiment may include a channel 315 that is a silicide, such as NiSi, TiSi, or CoSi.

In embodiments that include a silicide channel 315, the channel 315 may be formed with a silicide formation process. In an embodiment, the silicide formation process may include disposing a layer of a-silicon or polysilicon over the exposed surfaces of the insulation layer 303 between the S/D region 305. According to an embodiment, the thickness of the a-silicon or polysilicon may be less than the desired thickness T of the channel. By way of example, the a-silicon or polysilicon layer may be less than 5 nm. In an embodiment, the a-silicon or polysilicon layer is less than approximately 1.0 nm. After the a-silicon or polysilicon has been deposited, a metal layer that will form a silicide with the a-silicon or polysilicon is formed over the a-silicon or polysilicon layer. In an embodiment, the metal may be Fe, Ni, Ti, Co, or any other silicide forming metal. According to an embodiment, the device may then be heated to allow the metal and silicon layers to react with each other to form a silicide.

In an embodiment, the band-gap of the channel 315 may be modulated by forming a surface termination on the exposed surfaces of the channel 315. As illustrated in the graph in FIG. 1A, each termination species may produce different band-gaps for a given thickness of the channel 315. By way of example, the surface termination species may be CH₃, F, H, or OH. According to an embodiment, the surface termination may be applied at the same time the channel 315 is deposited. For example, a final pulse of an ALD deposition process may include a source gas containing the surface termination species.

Additional embodiments may include applying the surface termination species after subsequent processing operations. For example, the gate dielectric 314 and gate electrode 316 may be formed before the surface termination is applied to the channel 315. In such embodiments, the termination species may be implanted through the layers disposed over the channel 315. For example, when hydrogen is utilized as the surface termination, hydrogen ions may be implanted through the gate electrode 316 and gate dielectric 314 in order to reach the channel 315.

Referring now to FIG. 3D, a gate dielectric layer 314 is formed over the exposed surfaces of the channel material 312 and the channel 315. In an embodiment, the gate dielectric layer 314 may be a high-k dielectric material. For example, the dielectric layer 314 may be hafnium oxide or zirconium oxide. According to an embodiment, the gate oxide may be between approximately 2 nm and 3 nm thick. In an embodiment, the gate oxide may be deposited with CVD, PVD, or ALD.

Referring now to FIG. 3E, a conductive material is deposited over the exposed surfaces of the gate dielectric layer 314 to form a gate electrode 316. As described above, the material used for the gate electrode 316 may be chosen to provide the desired threshold voltage of the MOMFET device. According to an embodiment, the top surface of the MOMFET device may be planarized after the material for the gate electrode 316 has been deposited. For example, planarization may be performed with a chemical-mechanical polishing (CMP) process. In an embodiment, the planarization may remove excess channel material 312, gate dielectric material 314, and gate electrode material 316 disposed above top surfaces of the S/D regions 305.

In an additional embodiment, a second MOMFET device may be formed above the top surface of the first MOMFET device to form a 3-D integrated structure such as the one described above with respect to FIG. 2B. In such an embodiment, the processing described with respect to FIGS. 3A-3F may be repeated, with the exception that a substrate layer 301 is not required. Instead, a second insulation layer may be formed over the exposed surfaces of the first MOMFET device, as illustrated in FIG. 2B. The second insulation layer may be substantially similar to the first insulation layer 303. According to an additional embodiment, the process for forming MOMFET devices stacked on top of each other may be repeated any number of times to produce a 3-D integrated package with the desired number of MOMFET layers.

Due to the bipolar nature of the channel, embodiments of the invention are able to form complimentary metal-oxide-metal (CMOM) inverters without having to dope P-wells and N-wells, as is the case when a complementary metal-oxide-semiconductor (CMOS) inverter is formed. Instead, embodiments of the invention can form a P-type MOMFET and an N-type MOMFET that are electrically coupled by using different materials for the gate electrode for each MOMFET, by using different materials for the S/D regions for each MOMFET, or a combination thereof.

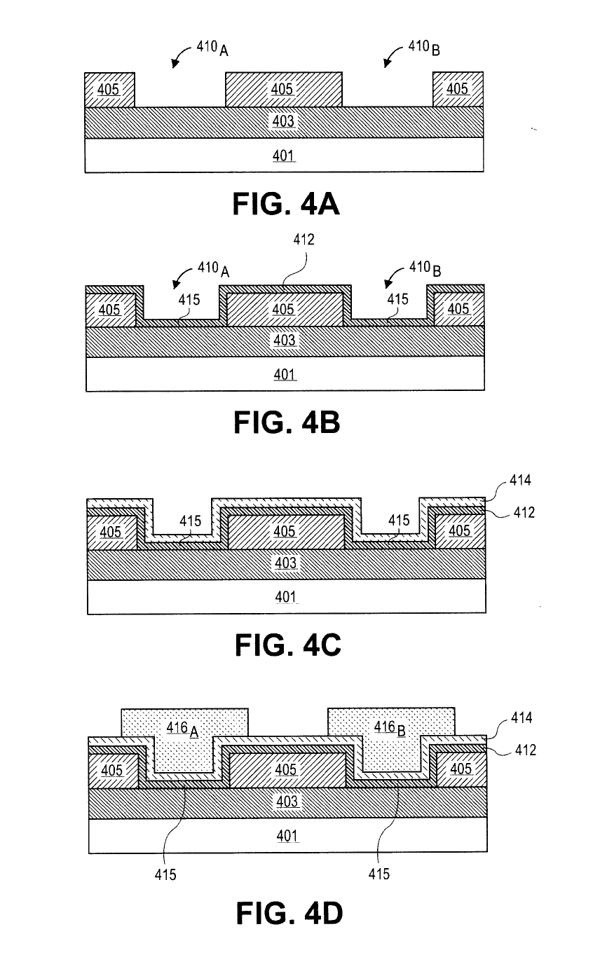

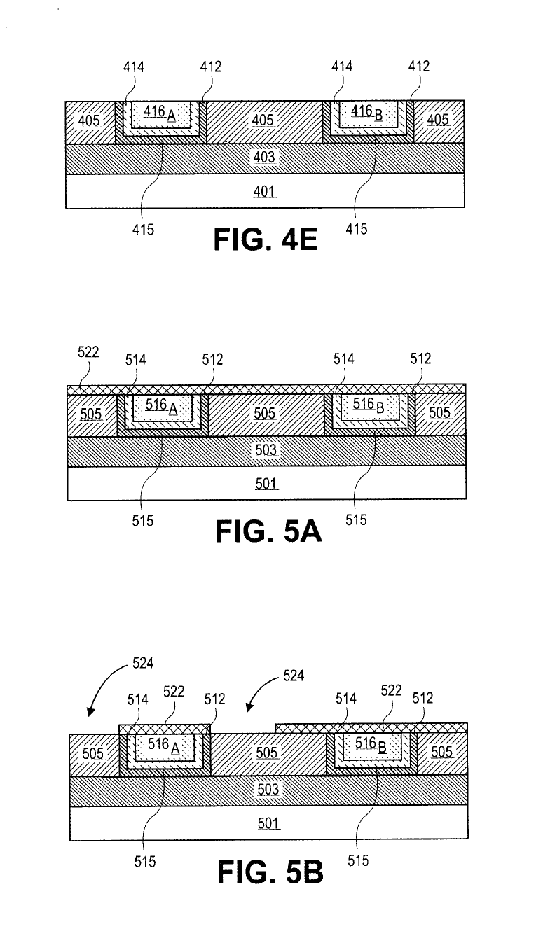

According to embodiments of the invention, a CMOM inverter may be formed with a process such as the one illustrated in FIGS. 4A-4E. Referring now to FIG. 4A, openings 410_{A} and 410_{B} have been formed through a S/D layer to expose a portion of the insulating layer 403 and to define S/D regions 405. Aside from forming two openings, the materials and processing used to form the structure illustrated in FIG. 4A are substantially similar to the processing and materials described above with respect to FIGS. 3A and 3B.

Referring now to FIG. 4B, a channel material 412 is disposed over the exposed surfaces of the S/D regions 405 and the exposed surfaces of the insulating layer 403. The portion of the channel material formed on the insulating layer and between the S/D regions 405 may be considered the channel 415. According to an embodiment, the channel 415 is formed from a material in which a band-gap develops when the thickness of the channel 415 produces a quantum confinement effect in the channel 415. In an embodiment, the thickness of the channel 415 is chosen to provide the desired band-gap. For example, as the thickness of the channel 415 is decreased, the band-gap increases. In an embodiment, the thickness may be between approximately 1 nm and 5 nm in order to produce a desired band-gap in the channel 415. Embodiments include a channel 415 that may be a metal, semi-metal, bismide, rare-earth pnictides, Group IV-b/IV-a compound, transition metal compound, or silicide such as those described above with respect to FIG. 3C. According to embodiments, the channel 415 is formed form the same material as the S/D regions 405.

Referring now to FIG. 4C, a gate dielectric 414 may be formed over the channel 415 and the channel material layer 412 formed along the sidewall and top surface of the S/D regions 405. According to an embodiment, the gate dielectric 414 may be a high-k dielectric that is substantially similar to the gate dielectric described above with respect to FIG. 3D.

Referring now to FIG. 4D, the gate electrode material 416_{A} and 416_{E} may be deposited into the openings. According to an embodiment, the material used for gate electrode 416_{A} is different than the material used for gate electrode 416_{B}. By way of example, the materials used for 416_{A} and 416_{B} have different work-functions. The different work-functions allow for the formation of an N-type and a P-type MOMFET device when the S/D regions 405 and the channel 415 are formed from the same material. For example, the material used for gate electrode 416_{A} may have a higher work-function than the work-function for gate electrode 416_{B}. In such an embodiment, the gate electrode 416_{A} may allow for the formation of an N-type device, and the gate electrode 416_{B} may allow for the formation of a P-type device. Accordingly, a CMOM inverter may be formed since the N-MOM and P-MOM devices are coupled by the S/D region 405 between them.

Referring now to FIG. 4E, the CMOM inverter may be planarized to expose top surfaces of the S/D regions 405. For example, planarization may be performed with a CMP process. In an embodiment, the planarization may remove excess channel material 414, gate dielectric material 414, and gate electrode material 416 disposed above top surfaces of the S/D regions 405.

Additionally, a second CMOM inverter may be formed above the top surface of the first CMOM inverter to form a 3-D integrated structure. In such an embodiment, the processing described with respect to FIGS. 4A-4E may be repeated, with the exception that a substrate layer 401 is not required. Instead, a second insulation layer 403 may be formed over the exposed surfaces of the first CMOM inverter. According to an additional embodiment, the process of forming CMOM inverters stacked on top of each other may be repeated any number of times to produce a 3-D integrated package with the desired number of CMOM inverter layers.

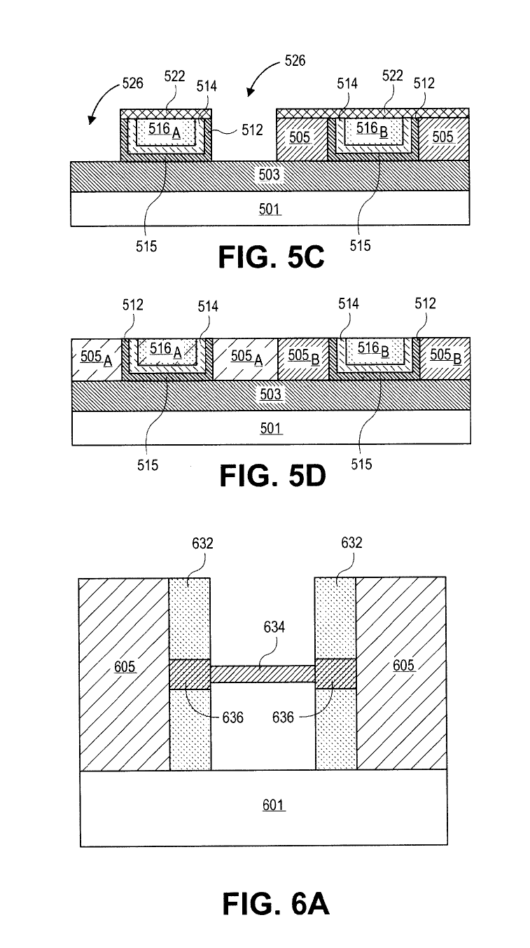

According to an additional embodiment, a CMOM inverter may also be formed by creating complimentary N-MOM and a P-MOM devices that have the same material used for the gate electrodes. As such, the conductivity type of each transistor is determined by selecting different materials for the S/D regions of each transistor. FIGS. 5A-5D illustrate a method of forming such a device according to an embodiment.

Referring now to FIG. 5A, a CMOM inverter substantially similar to the one described in FIG. 4E is illustrated, with the exception that the gate electrodes 516_{A} and 516_{E} are formed from the same material. Additionally, a mask layer 522 is disposed over the top surface of the transistors. The mask layer 522 may be any mask layer that is typically used in patterning and etching processes, such as a photo-definable mask layer. As shown in FIG. 5B, openings 524 are patterned into the mask layer 522. The openings expose portions of the S/D regions 505. In an embodiment, the mask layer 522 covers the portions of the channel material 512 formed along the sidewalls of the S/D regions 505. However, embodiments are not limited to such configurations, and the openings 524 may also expose portions of the channel material 512 formed along the sidewalls of the S/D region according to additional embodiments.

Thereafter, embodiments include removing the exposed S/D regions 505, as illustrated in FIG. 5C. In an embodiment, the S/D regions 505 are removed with an etching process to form openings 526 proximate to a gate electrode 516_{A}. In embodiments where the portions of the channel material 512 formed along the sidewalls of the S/D regions 505 are also exposed, the channel material 512 formed along the sidewalls may be etched away as well. Thereafter, a replacement S/D region 505_{A} is deposited in the openings 526. According to an embodiment, the replacement S/D region 505_{A} may be a material with a work-function that produces a conductivity type in the MOMFET that is different than the conductivity type formed by the combination of the gate electrode 516_{B} and the original S/D regions 505_{B}.

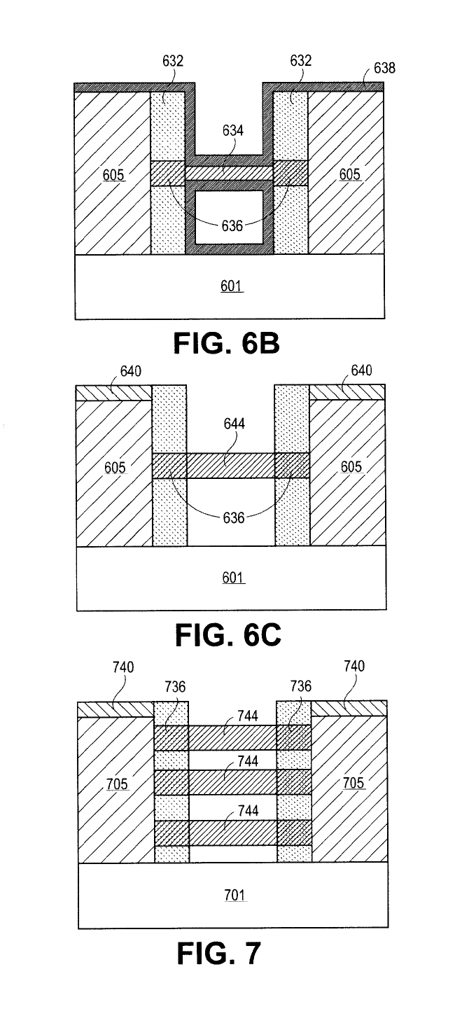

According to an additional embodiment, a MOMFET device may also be formed with a nanowire channel. A process for forming such a MOMFET is illustrated in FIGS. 6A-6C. In FIG. 6A, a silicon nanowire 636 is formed between heavily doped silicon S/D regions 605. By way of example, the silicon nanowire may be an a-silicon or a polysilicon. In order to obtain the desired diameter of the channel formed in the nanowire 636, a spacer 632 may be formed along the sidewalls of the S/D regions 605, and over a portion of the silicon nanowire 636. The diameter of the nanowire is then reduced with an etching process to form a channel portion 634 of the nanowire. By way of example, the channel portion 634 may have a diameter that is less than approximately 5.0 nm. In an embodiment, the diameter of the channel portion 634 may be approximately 1.0 nm or less.

Referring now to FIG. 6B, a metallic layer 638 may be deposited over the exposed surfaces of the S/D regions 606, and the channel portion 634 of the nanowire. According to an embodiment, the metallic layer 638 may be between approximately 3.0 nm and 5.0 nm thick. In an embodiment, the metallic layer 638 may be a transition metal that will form a silicide with the channel portion 634 of the nanowire. For example, the metallic layer 638 may be Fe, Ni, Co, or Ti.

After the metallic layer 638 is formed, a silicide channel 644 may be formed. According to an embodiment, the silicide channel 644 may be formed by reacting the metallic layer 638 with the channel portion 634. In an embodiment, the silicide formation, may completely consume the silicon that formed the channel portion 634. In an embodiment, the diameter of the channel portion 634 may increase as a result of the silicide formation. In an embodiment, unconsumed portions of the metallic layer 638 may be removed. For example, the excess metal may be removed with an etching process. According to an embodiment, the metallic layer 638 may also react with the S/D regions 605 to form a silicide layer 640 over portions of the S/D regions 605. Thereafter, a gate dielectric may be formed around the silicide channel 644, and a gate electrode may be disposed around the gate dielectric in order to form a gate all around (GAA) nanowire, according to an embodiment. The gate dielectric and the gate electrode are omitted from FIG. 6C in order to not unnecessarily obscure the figure.

An additional embodiment of the invention is illustrated in FIG. 7. FIG. 7 is a cross-sectional illustration of a nanowire silicide MOMFET device that includes a plurality of nanowires. According to an embodiment, the device is substantially similar to the one described with respect to FIG. 6C, with the exception that more than one nanowire 744 is formed between the S/D regions 705. While three nanowires 744 are illustrated in FIG. 7, embodiments are not so limited. By way of example, there may be two or more nanowires 744 formed between the S/D regions.

While embodiments described herein illustrate the formation of MOMFET devices with planar and nanowire channel architectures, embodiments are not limited to such configurations. Additional embodiments include MOMFET devices formed in any channel geometry or orientation that include a channel with at least one confined dimension that produces a quantum confinement effect in the channel. By way of example, embodiments may also include fin shaped channels and channels that are oriented in the horizontal or vertical directions.

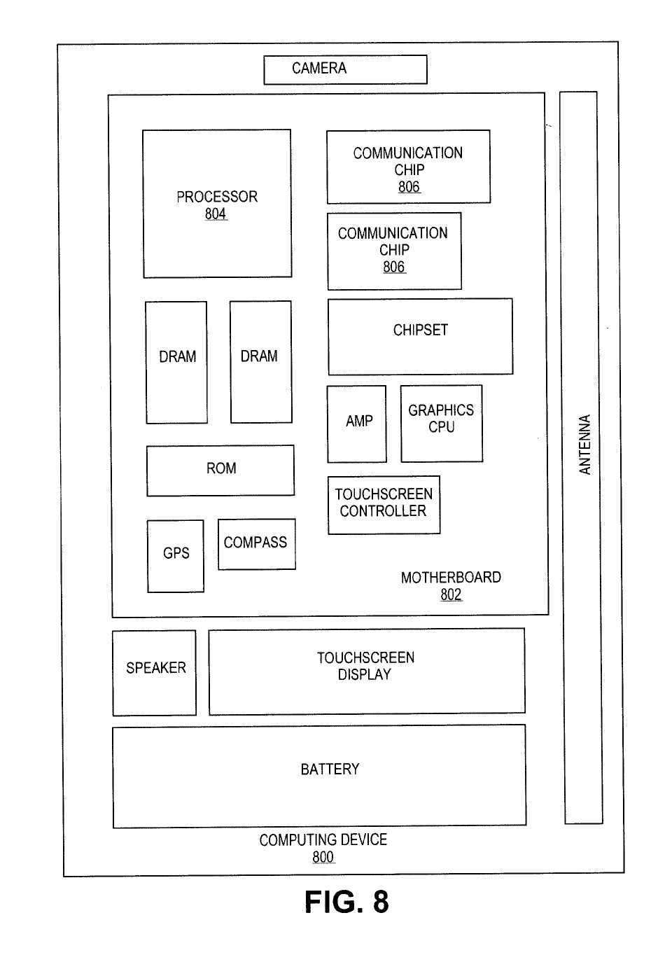

FIG. 8 illustrates a computing device 800 in accordance with an embodiment. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some embodiments, the integrated circuit die of the processor may include one or more MOMFET devices that have a channel with least one confined dimension that produces a quantum confinement effect in the channel, in accordance with an embodiment. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another embodiment, the integrated circuit die of the communication chip may include one or more MOMFET devices that have a channel with least one confined dimension that produces a quantum confinement effect in the channel, in accordance with an embodiment.

In further implementations, another component housed within the computing device 800 may contain an integrated circuit that may include one or more MOMFET devices that have a channel with least one confined dimension that produces a quantum confinement effect in the channel, in accordance with an embodiment.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

An embodiment of the invention includes a semiconductor device comprising, a source and a drain, wherein the source and the drain are formed with a material having a first work-function, a channel disposed between the source and the drain, wherein the channel is a material selected from a group consisting of semimetals, bismides, rare-earth pnictides, Group IV-b/IV-a compounds, transition metal compounds, and silicides, and wherein the channel has a thickness less than 5.0 nm, and a gate electrode separated from the channel by a gate dielectric, the gate electrode having a second work-function. An additional embodiment includes a semiconductor device wherein, the channel is Sn, Pb, As, Sb, or Bi. An additional embodiment includes a semiconductor device wherein, wherein the channel is FeSi, NiSi, TiSi, or CoSi. An additional embodiment includes a semiconductor device wherein, the channel has a band-gap that is between approximately 0.5 eV and 1.5 eV. An additional embodiment includes a semiconductor device wherein, wherein a surface termination is formed over a surface of the channel. An additional embodiment includes a semiconductor device wherein, the surface termination is CH₃, F, H, or OH. An additional embodiment includes a semiconductor device further comprising, an insulating layer formed below the source and drain, wherein the channel is disposed on a surface of the insulating layer between the source and drain. An additional embodiment includes a semiconductor device wherein the source and drain are the same material as the channel. An additional embodiment includes a semiconductor device, wherein the channel is a nanowire or a fin.

An embodiment of the invention includes a semiconductor device comprising, a first source and a first drain, wherein the first source and the first drain are formed with a material having a first work-function, a first channel disposed between the first source and the first drain, wherein the first channel has at least one confined dimension that produces a quantum confinement effect in the first channel, a first gate electrode separated from the first channel by a first gate dielectric, the first gate electrode having a second work-function, a second source and a second drain, wherein the second the source and the second drain are formed with a material having a third work-function, a second channel disposed between the second source and second drain, wherein the second channel has at least one confined dimension that produces a quantum confinement effect in second the channel, and a second gate electrode separated from the second channel by a second gate dielectric, the second gate electrode having a fourth work-function. An embodiment of the invention includes a semiconductor device, wherein the first and third work-functions are the same, and wherein the second and fourth work-functions are different. An embodiment of the invention includes a semiconductor device, wherein the first and third work-functions are different, and wherein the second and fourth work-functions are the same. An embodiment of the invention includes a semiconductor device, wherein the first drain is electrically coupled to the second source. An embodiment of the invention includes a semiconductor device, wherein the first and second channel are a semimetal, a bismide, a rare-earth pnictide, a Group IV-b/IV-a compound, a transition metal compound, or a silicide. An embodiment of the invention includes a semiconductor device, wherein the confined dimensions of the first and second channel are less than approximately 5.0 nm, and wherein the first and second channels have a band-gap that is between approximately 0.5 eV and 1.5 eV.

An embodiment of the invention includes a method of forming a semiconductor device comprising, providing a source/drain (S/D) layer over an insulating layer, wherein the S/D layer has a first work-function, forming an opening through the S/D layer to define S/D regions, forming a channel above the exposed surfaces of the insulating layer, wherein the channel has at least one confined dimension that produces a quantum confinement effect in the channel, forming a gate dielectric over the channel, forming a gate electrode over the gate dielectric, wherein the gate electrode has a second work-function. The method of claim 16, wherein the channel is a semimetal, a bismide, a rare-earth pnictide, a Group IV-b/IV-a compound, a transition metal compound, or a silicide. An embodiment of the invention includes method of forming a semiconductor device further comprising, disposing a surface termination species over a surface of the channel. An embodiment of the invention includes method of forming a semiconductor device, wherein the surface termination species is CH₃, F, H, or OH. An embodiment of the invention includes method of forming a semiconductor device, wherein the surface termination species is formed subsequent to the formation of the gate electrode.

An embodiment of the invention includes a semiconductor device comprising, a source and a drain, wherein the source and the drain are formed with a material having a first work-function, a channel disposed between the source and the drain, wherein the channel has at least one confined dimension that produces a quantum confinement effect in the channel, and a gate electrode separated from the channel by a gate dielectric, the gate electrode having a second work-function. An embodiment of the invention includes a semiconductor device, wherein the channel is a semimetal, a bismide, a rare-earth pnictide, a Group IV-b/IV-a compound, a transition metal compound, or a silicide. An embodiment of the invention includes a semiconductor device, wherein the channel is Sn, Pb, As, Sb, Bi, FeSi, NiSi, TiSi, or CoSi. An embodiment of the invention includes a semiconductor device, wherein the confined dimension of the channel is less than approximately 5.0 nm. An embodiment of the invention includes a semiconductor device, wherein the channel has a band-gap that is between approximately 0.5 eV and 1.5 eV.

What is claimed is:

1. A semiconductor device comprising:
a source and a drain, wherein the source and the drain are formed with a material having a first work-function;
a channel disposed between the source and the drain, wherein the channel is a material selected from a group consisting of semimetals, bismides, rare-earth pnictides, Group IV-b/IV-a compounds, transition metal compounds, and silicides, and wherein the channel has a thickness less than 5.0 nm; and
a gate electrode separated from the channel by a gate dielectric, the gate electrode having a second work-function.

2. The device of claim 1, wherein the channel is Sn, Pb, As, Sb, or Bi.

3. The device of claim 1, wherein the channel is FeSi, NiSi, TiSi, or CoSi.

4. The device of claim 1, wherein the channel has a band-gap that is between approximately 0.5 eV and 1.5 eV.

5. The device of claim 1, wherein a surface termination is formed over a surface of the channel.

6. The device of claim 5, wherein the surface termination is CH₃, F, H, or OH.

7. The device of claim 1 further comprising:
an insulating layer formed below the source and drain, wherein the channel is disposed on a surface of the insulating layer between the source and drain.

8. The device of claim 1, wherein the source and drain are the same material as the channel.

9. The device of claim 1, wherein the channel is a nanowire or a fin.

10. A semiconductor device comprising:
a first source and a first drain, wherein the first source and the first drain are formed with a material having a first work-function;
a first channel disposed between the first source and the first drain, wherein the first channel has at least one confined dimension that produces a quantum confinement effect in the first channel;
a first gate electrode separated from the first channel by a first gate dielectric, the first gate electrode having a second work-function;
a second source and a second drain, wherein the second the source and the second drain are formed with a material having a third work-function;
a second channel disposed between the second source and second drain, wherein the second channel has at least one confined dimension that produces a quantum confinement effect in second the channel; and
a second gate electrode separated from the second channel by a second gate dielectric, the second gate electrode having a fourth work-function.

11. The device of claim 10, wherein the first and third work-functions are the same, and wherein the second and fourth work-functions are different.

12. The device of claim 10, wherein the first and third work-functions are different, and wherein the second and fourth work-functions are the same.

13. The device of claim 10, wherein the first drain is electrically coupled to the second source.

14. The device of claim 10, wherein the first and second channel are a semimetal, a bismide, a rare-earth pnictide, a Group IV-b/IV-a compound, a transition metal compound, or a silicide.

15. The device of claim 10, wherein the confined dimensions of the first and second channel are less than approximately 5.0 nm, and wherein the first and second channels have a band-gap that is between approximately 0.5 eV and 1.5 eV.

16. A method of forming a semiconductor device comprising:
providing a source/drain (S/D) layer over an insulating layer, wherein the S/D layer has a first work-function;
forming an opening through the S/D layer to define S/D regions;
forming a channel above the exposed surfaces of the insulating layer, wherein the channel has at least one confined dimension that produces a quantum confinement effect in the channel;
forming a gate dielectric over the channel; and
forming a gate electrode over the gate dielectric, wherein the gate electrode has a second work-function.

17. The method of claim 16, wherein the channel is a semimetal, a bismide, a rare-earth pnictide, a Group IV-b/IV-a compound, a transition metal compound, or a silicide.

18. The method of claim 16, further comprising:
disposing a surface termination species over a surface of the channel.

19. The method of claim 18, wherein the surface termination species is CH₃, F, H, or OH.

20. The method of claim 18, wherein the surface termination species is formed subsequent to the formation of the gate electrode.

21. A semiconductor device comprising:
a source and a drain, wherein the source and the drain are formed with a material having a first work-function;
a channel disposed between the source and the drain, wherein the channel has at least one confined dimension that produces a quantum confinement effect in the channel; and
a gate electrode separated from the channel by a gate dielectric, the gate electrode having a second work-function.

22. The device of claim 21, wherein the channel is a semimetal, a bismide, a rare-earth pnictide, a Group IV-b/IV-a compound, a transition metal compound, or a silicide.

23. The device of claim 22, wherein the channel is Sn, Pb, As, Sb, Bi, FeSi, NiSi, TiSi, or CoSi.

24. The device of claim 21, wherein the confined dimension of the channel is less than approximately 5.0 nm.

25. The device of claim 21, wherein the channel has a band-gap that is between approximately 0.5 eV and 1.5 eV.
